(19) United States
(12) Patent Application Publication
(10) Pub. No.: US 2025/0287624 A1
(43) Pub. Date: Sep. 11, 2025

(54) POWER SEMICONDUCTOR DEVICE

(71) Applicant: Mitsubishi Electric Corporation, Tokyo (JP)

(72) Inventors: Hiroya HAMADA, Tokyo (JP); Tsuyoshi OSAGA, Tokyo (JP); Rui KONISHI, Tokyo (JP)

(73) Assignee: Mitsubishi Electric Corporation, Tokyo (JP)

(21) Appl. No.: 18/855,922

(22) PCT Filed: Jun. 15, 2022
(86) PCT No.: PCT/JP2022/023945

§ 371 Date: Oct. 10, 2024

(51) Int. Cl. H10D 12/00; H01L 23/00; H01L 23/36

(52) U.S. Cl. CPC H10D 12/481; H01L 23/36; H01L 24/40; H01L 24/32; H01L 2224/32245; H01L 2224/40

(57) ABSTRACT

A power semiconductor device with a semiconductor substrate includes a first active region provided in a central portion of the semiconductor substrate and a second active region provided outside the first active region, the power semiconductor device including: a first main electrode; and a second main electrode, in which the second active region has first two sides and second two sides, a distance of the first active region from a center of the semiconductor substrate is set to less than ¼ of a shorter length of a first length between the first two sides of the second active region or a second length between the second two sides of the second active region in a case where the first length and the second length are different, and is set to less than ¼ of either length in a case where the first length and the second length have no difference.

### TECHNICAL FIELD

The present disclosure relates to a power semiconductor device, and relates to a power semiconductor device in which a maximum bonding temperature of a semiconductor substrate is lowered.

### BACKGROUND ART

In a power semiconductor device such as a power insulated gate bipolar transistor (IGBT), a power metal oxide semiconductor field effect transistor (MOSFET), and a power diode, it is a problem to lower a maximum junction temperature (TjMAX) of a semiconductor substrate. For example, Patent Document 1 discloses a technique for suppressing TjMAX by making the conduction capability of the cell structure in the central portion of the semiconductor substrate smaller than that of the cell structure in the outer peripheral portion.

This technique is a technique for suppressing TjMAX by reducing heat generation at a central portion of a semiconductor substrate having low heat dissipation. However, when a region having a small conduction capability is too wide, energy loss increases, and conversely, TjMAX may increase.

### PRIOR ART DOCUMENT

### Patent Document

Patent Document 1: Japanese Patent Application Laid-Open No. 2010-4003

### SUMMARY

### Problem to be Solved by the Invention

In the conventional technique disclosed in Patent Document 1, in order to lower TjMAX, the conduction capability of the cell structure in the central portion of the semiconductor substrate having low heat dissipation is made smaller than that of the cell structure in the outer peripheral portion. However, when the region of the cell structure having low conduction capability is made too large, energy loss increases, and thus some condition setting is required. However, Patent Document 1 does not sufficiently disclose the condition setting.

The present disclosure has been made to solve the above problems, and an object of the present disclosure is to provide a power semiconductor device capable of reliably suppressing TjMAX.

### Means to Solve the Problem

A power semiconductor device according to the present disclosure is a power semiconductor device in which a main current flows in a thickness direction of a semiconductor substrate, the semiconductor substrate including: a first active region provided in a central portion of the semiconductor substrate and through which the main current flows; and a second active region provided outside the first active region, the power semiconductor device including: a first main electrode provided on the first and second active regions; and a second main electrode provided on a main surface of the semiconductor substrate opposite to the first main electrode, in which the second active region has first two sides facing each other in a first direction and second two sides facing each other in a second direction orthogonal to the first direction, a distance of the first active region from a center of the semiconductor substrate is set to less than ¼ of a shorter length of a first length between the first two sides of the second active region or a second length between the second two sides of the second active region in a case where the first length and the second length are different, and is set to less than ¼ of either length in a case where the first length and the second length have no difference, and a first conduction capability of the first active region is set lower than a second conduction capability of the second active region.

### Effects of the Invention

According to the power semiconductor device according to the present disclosure, heat generation can be suppressed at the central portion of the semiconductor substrate, and the maximum bonding temperature can be reliably suppressed.

### BRIEF DESCRIPTION OF DRAWINGS

FIG. 1 is a schematic cross-sectional view of a power semiconductor device according to a first embodiment of the present disclosure.

FIG. 2 is a plan view of a semiconductor substrate of the power semiconductor device according to the first embodiment of the present disclosure.

FIG. 3 is a diagram showing an area dependence of an active region of a maximum junction temperature of the semiconductor substrate of the power semiconductor device according to the first embodiment of the present disclosure.

FIG. 4 is a partial cross-sectional view showing a configuration of a power semiconductor device according to a second embodiment of the present disclosure.

FIG. 5 is a partial cross-sectional view showing a configuration of a power semiconductor device according to a third embodiment of the present disclosure.

FIG. 6 is a partial cross-sectional view showing a configuration of a power semiconductor device according to a fourth embodiment of the present disclosure.

FIG. 7 is a partial cross-sectional view showing a configuration of a power semiconductor device according to a fifth embodiment of the present disclosure.

### DESCRIPTION OF EMBODIMENTS

### Introduction

Hereinafter, embodiments of the present disclosure will be described with reference to the accompanying drawings. Note that the drawings are schematically shown, and the dimensions in the horizontal direction and the vertical direction of each component in the drawings do not accurately represent the actual dimensions, and the dimensional ratio is not accurate. In addition, in the following description, similar components are denoted by the same reference numerals, and names and functions thereof are also similar. Therefore, a detailed description thereof may be omitted.

In addition, in the following description, terms meaning specific positions and directions such as “upper”, “lower”, “side”, “front”, or “back” may be used, but these terms are used for convenience to facilitate understanding of the contents of the embodiments and are not related to directions when actually implemented.

In addition, in the following description, “outside” is a direction toward the outer periphery of the semiconductor substrate, and “inside” is a direction opposite to “outside”.

In addition, n and p represent the conductivity type of the semiconductor, and in the present disclosure, the first conductivity type is described as n type and the second conductivity type is described as p type, but the first conductivity type may be p type and the second conductivity type may be n type. In addition, n type indicates that the impurity concentration is lower than n type, and n⁺ type indicates that the impurity concentration is higher than n type. Similarly, p indicates that the impurity concentration is lower than p, and p⁺ indicates that the impurity concentration is higher than p.

### First Embodiment

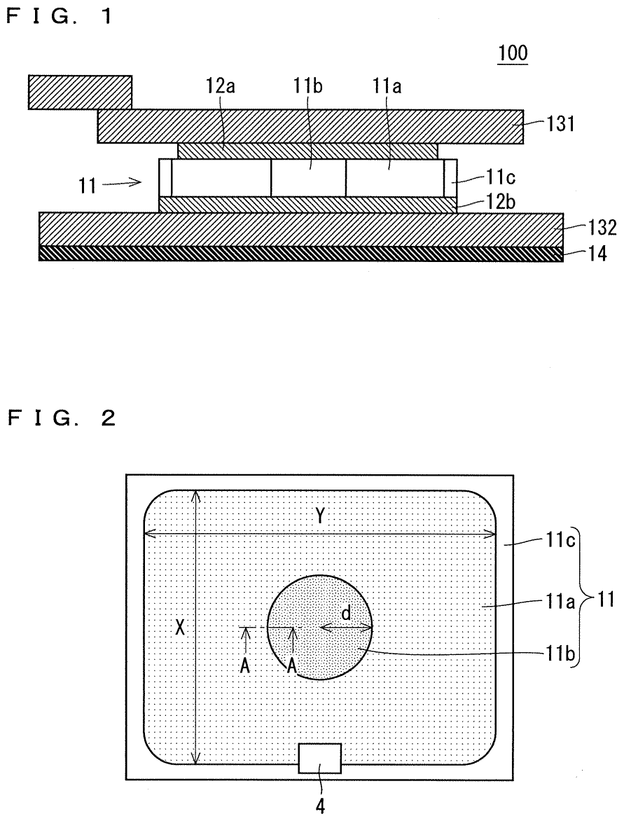

FIG. 1 is a schematic cross-sectional view of a power semiconductor device according to a first embodiment of the present disclosure. Note that the power semiconductor device may be any of a power IGBT, a power MOSFET, and a power diode, but will be described as a power IGBT100 as an example.

As shown in FIG. 1, in the power IGBT100, a semiconductor substrate 11 is bonded onto a heat dissipation plate 132 via a conductive bonding layer 12b (second bonding layer) such as a solder layer. A collector electrode (not shown) is provided on the lower surface (second main surface) of the semiconductor substrate 11, and the heat dissipation plate 132 is directly bonded to the collector electrode via the bonding layer 12b. An insulating sheet 14 is provided on the lower surface of the heat dissipation plate 132.

A conductor plate 131 is bonded to the upper surface (first main surface) of the semiconductor substrate 11 via a conductive bonding layer 12a (first bonding layer) such as a solder layer. An emitter electrode (not shown) is provided on the upper surface of the semiconductor substrate 11, and the conductor plate 131 is directly bonded to the emitter electrode via the bonding layer 12b. The semiconductor substrate 11 includes, as active regions through which a main current flows, an active region 11b (first active region) provided in a substrate central portion, an active region 11a (second active region) surrounding the active region 11b, and a termination region 11c outside the active region 11a. The active region 11b is an active region in which the conduction capability (collector current) per unit area is lower than that of the active region 11a.

Although not shown in FIG. 1, the power IGBT100 is housed in a resin case, the insulating sheet 14 on the lower surface of the heat dissipation plate 132 is exposed from the bottom surface of the resin case, and the resin case is filled with a sealing resin (not shown). The power IGBT100 resin-sealed in the resin case as described above is mounted on a heat dissipation member such as a heat sink, so that the cooling capacity can be enhanced. Note that a conductor plate may be provided under the insulating sheet 14, and the conductor plate may be exposed from the bottom surface of the resin case.

The bonding layer 12a is provided only in a region excluding a region where a configuration for inputting a gate signal such as a gate wiring and a gate pad (not shown) is provided, that is, only on an emitter electrode (not shown), whereas the bonding layer 12b is provided over the entire surface of a collector electrode (not shown) provided on the entire lower surface (second main surface) of the semiconductor substrate 11. Therefore, heat dissipation of the semiconductor substrate 11 can be secured.

FIG. 2 is a plan view of the semiconductor substrate 11 of FIG. 1 as viewed from above, and the bonding layer 12a and the conductor plate 131 are omitted for convenience.

In FIG. 2, the active region 11b is provided as a circular region, and its radius is indicated as “d”. The radius d of the active region 11b is set to satisfy d≤X/4. In FIG. 2, X is a length between two long sides, and can be said to be a first length between first two sides facing each other in a first direction. In addition, Y is a length between two short sides, and can be said to be a second length between second two sides facing each other in a second direction orthogonal to the first direction.

Note that the plan view shape of the active region 11b is not limited to a circular shape, and in the case of FIG. 2, the plan view shape can be a quadrangle as long as it is within a range of less than ¼ of the length X of the active region 11a in the vertical direction. In FIG. 2, the plan view shape of the active region 11a is a rectangle in which the relationship between the length Y in the horizontal direction in plan view and the length X in the vertical direction is X<Y, but X≤Y is sufficient, and the plan view shape may be a square.

In FIG. 2, a gate pad 4 is provided at the center of the lower side of the semiconductor substrate 11, but the position of the gate pad 4 is not limited thereto. Although a gate wiring (not shown) is connected to the gate pad 4, the gate wiring can be provided along the periphery of the active region 11a.

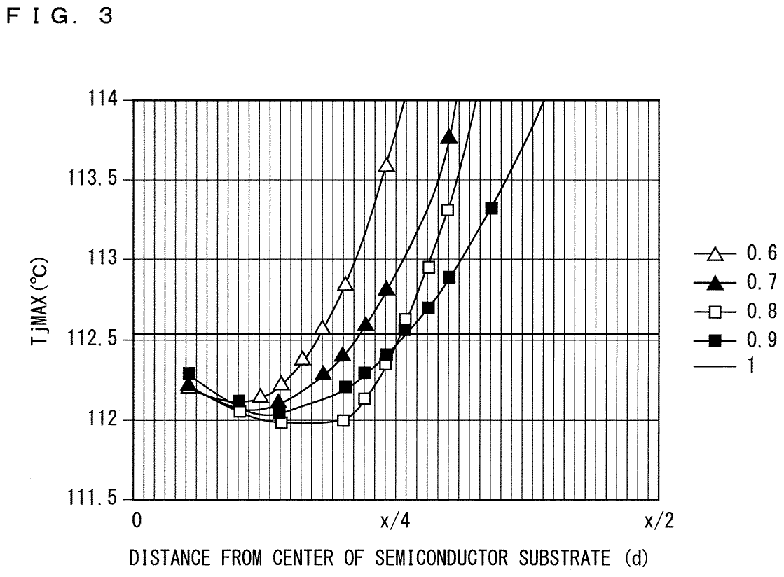

FIG. 3 is a diagram showing the area dependence of the maximum junction temperature (TjMAX) of the semiconductor substrate 11 on the active region 11b when the total current of the entire semiconductor substrate 11 is always constant and the conduction capability ratio of the active region 11b to the active region 11a is 1 (straight line), 0.9 (▪ plot), 0.8 (□ plot), 0.7 (plot), and 0.6 (Δ plot) in the power IGBT100 of FIG. 1.

In FIG. 3, the horizontal axis represents the distance (d) from the center of the semiconductor substrate corresponding to the radius d of the active region 11b, and the vertical axis represents TjMAX (° C.).

In FIG. 3, when the conduction capability ratio of the active region 11b is 1, that is, when the conduction capabilities of the active region 11a and the active region 11b are the same, TjMAX is constant at about 112.6° C. regardless of the radius d from the center of the semiconductor substrate. However, when the conduction capability of the active region 11b becomes smaller than that of the active region 11a, it is found that the energization TjMAX varies depending on the radius d from the center of the semiconductor substrate, that is, the area of the active region 11b.

For example, when the conduction capability ratio of the active region 11b is 0.8, TjMAX becomes 112° C. in the vicinity of the radius d of X/4, and thereafter, TjMAX rapidly increases as the radius d approaches X/4.

This characteristic is the same for the other conduction capability ratios, and has a characteristic of being a minimum value at a temperature close to 112° C. As described above, when the conduction capability ratio of the active region 11b is less than 1, and the radius d of the active region 11b from the center of the semiconductor substrate 11 is within a range of less than ¼ of the length X of the vertical side of the active region 11a of the semiconductor substrate 11, TjMAX can be reduced as compared with the case where the conduction capability ratio of the active region 11b is 1. Since TjMAX increases when the radius d is too small, the radius d is desirably not smaller than X/8.

This effect can be enhanced by a structure in which the power IGBT100 dissipates heat to the bonding layer 12b on the back surface side and also dissipates heat through the bonding layer 12a on the front surface side. That is, in the power IGBT100, since the conductor plate 131 is directly bonded to the semiconductor substrate 11 by direct lead bonding (DLB) with the bonding layer 12a interposed therebetween, heat can be dissipated to a metal frame or the like having high heat dissipation through the bonding layer 12a on the front surface side and the conductor plate 131.

On the other hand, when the active region 11b is made too wide, for example, when the radius d of the active region 11b from the center of the semiconductor substrate 11 is set to X/4 or more, it is found that TjMAX conversely increases.

When the radius d from the center of the semiconductor substrate is X/4 or more in the direction parallel to the vertical side of the active region 11a and in the direction parallel to the horizontal side of the active region 11a, the active region 11a has a large conduction capability, and thus does not depend on the length of Y under the condition of X≤Y. Therefore, TjMAX can be reliably suppressed by lowering the conduction capability in the range where the radius d from the center of the semiconductor substrate is less than X/4.

### Second Embodiment

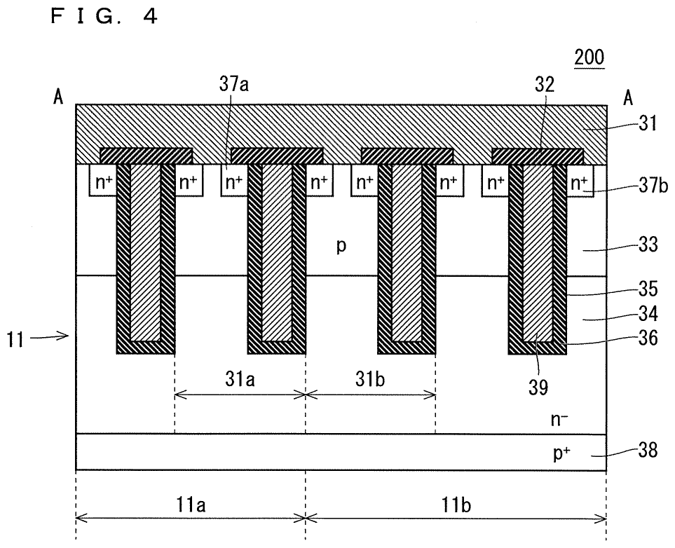

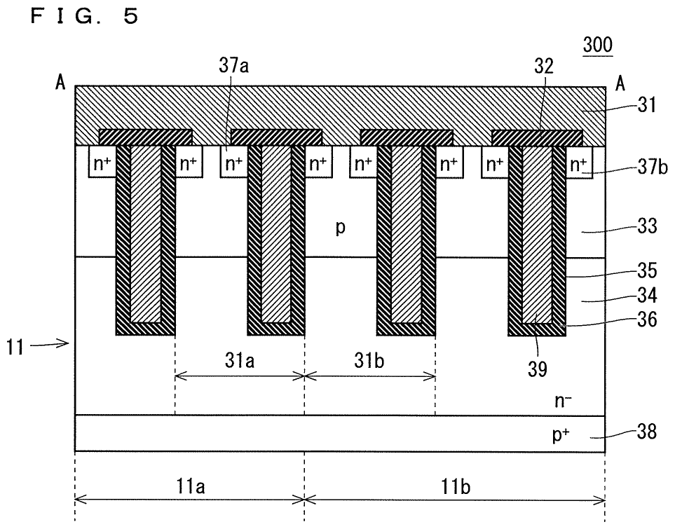

FIG. 4 is a cross-sectional view showing a configuration of a power IGBT200 according to a second embodiment of the present disclosure, and is a partial cross-sectional view of a semiconductor substrate 11 in the vicinity of a boundary region between an active region 11a and an active region 11b. Note that the overall cross-sectional view of the power IGBT200 is similar to that of the power IGBT100 shown in FIG. 1, and the same components are denoted by the same reference numerals, and redundant description is omitted.

FIG. 4 shows a cross-sectional configuration of the cell structure of the power IGBT200, and is a cross-sectional view taken along line A-A in the plan view of the semiconductor substrate 11 shown in FIG. 2.

In FIG. 4, a p⁺-type collector region 38 (first semiconductor region) is provided on the back surface side of the semiconductor substrate 11, an n⁻-type drift region 34 (second semiconductor region) is provided on the collector region 38, and a p-type body region 33 (third semiconductor region) is provided on the drift region 34.

In an upper layer portion of the body region 33, a plurality of n⁺-type source (emitter) regions 37a and 37b (fourth semiconductor regions) are selectively provided. In addition, a plurality of trenches 35 that penetrates the body region 33 from the outermost surface of the body region 33 and reaches the inside of the drift region 34 is provided. An arrangement interval 31a and an arrangement interval 31b of the trenches 35 in the active region 11a and the active region 11b are the same.

The inner wall of the trench 35 is covered with a gate insulating film 36, and a gate electrode 39 is filled inside the gate insulating film 36. The gate electrodes 39 are individually covered with the insulating films 32, and the upper surface of the semiconductor substrate 11 including the insulating films 32 is covered with the emitter electrode 31. A collector electrode is provided on a side opposite to the emitter electrode 31 across the semiconductor substrate 11, but is not shown for convenience.

One side surface of each of the source regions 37a and 37b is provided so as to be in contact with the side surface of the trench 35, that is, the side surface of the gate insulating film 36.

In FIG. 4, the source region 37b is provided in the active region 11b, and the source region 37a is provided in the active region 11a, but the impurity concentration of the n type impurity of the source region 37b is set to be lower than the impurity concentration of the n type impurity of the source region 37a. With this setting, the amount of carriers in the active region 11b decreases, and the conduction capability of the active region 11b is lower than the conduction capability of the active region 11a.

In order to make the conduction capability of the active region 11b lower than the conduction capability of the active region 11a, the impurity concentration of the source region 37b may be made lower than that of the source region 37a. For example, if the impurity concentration of the source region 37b is made lower than that of the source region 37a by 50%, the conduction capability can be lowered by 12%.

The source regions 37a and 37b can be separately formed by performing an impurity implantation process twice using an impurity implantation mask for forming the source region 37a and an impurity implantation mask for forming the source region 37b in a manufacturing process.

### Third Embodiment

FIG. 5 is a cross-sectional view showing a configuration of a power IGBT300 according to a third embodiment of the present disclosure, and is a partial cross-sectional view of a semiconductor substrate 11 in the vicinity of a boundary region between an active region 11a and an active region 11b. In FIG. 5, the same components as those of the power IGBT200 described with reference to FIG. 4 are denoted by the same reference numerals, and redundant description is omitted.

In FIG. 5, the source region 37b is provided in the active region 11b, the source region 37a is provided in the active region 11a, and although not shown, the region width of the source region 37b, that is, the length of the source region 37b in the direction along the extending direction of the gate electrode 39 is formed to be shorter than the region width of the source region 37a, that is, the length of the source region 37a in the direction along the extending direction of the gate electrode 39. By forming in this manner, the amount of carriers in the active region 11b decreases, and the conduction capability of the active region 11b is lower than the conduction capability of the active region 11a.

In order to make the conduction capability of the active region 11b lower than the conduction capability of the active region 11a, the region width of the source region 37b may be made shorter than that of the source region 37a. For example, if the region width of the source region 37b is made shorter than that of the source region 37a by 50%, the conduction capability can be lowered by 10%.

The source regions 37a and 37b can be separately formed in one impurity implantation process by using an impurity implantation mask in which the length of each implantation opening is changed in the impurity implantation mask for forming the source region 37a and the source region 37b in the manufacturing process.

### Fourth Embodiment

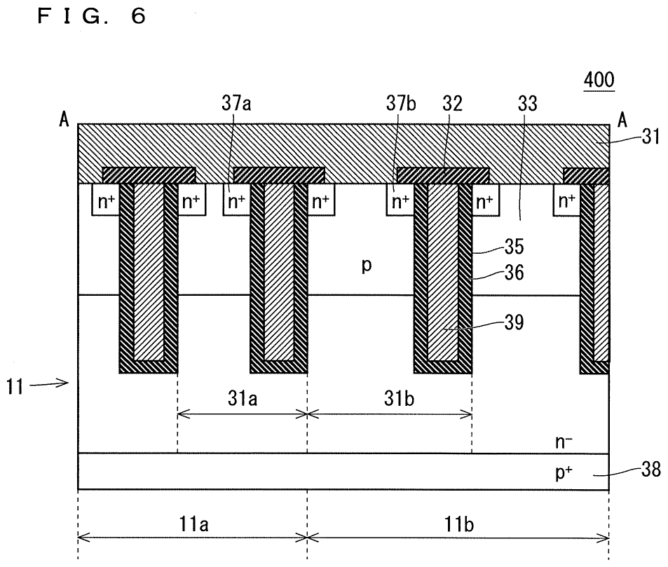

FIG. 6 is a cross-sectional view showing a configuration of a power IGBT400 according to a fourth embodiment of the present disclosure, and is a partial cross-sectional view of a semiconductor substrate 11 in the vicinity of a boundary region between an active region 11a and an active region 11b. In FIG. 6, the same components as those of the power IGBT200 described with reference to FIG. 4 are denoted by the same reference numerals, and redundant description is omitted.

In FIG. 6, an arrangement interval 31b of trenches 35 in the active region 11b is set to be wider than an arrangement interval 31a of trenches 35 in the active region 11a. By forming in this manner, the carrier accumulation effect in the active region 11b is reduced, and the conduction capability of the active region 11b is lower than the conduction capability of the active region 11a.

The carrier accumulation effect is an effect of reducing the on-resistance and suppressing the on-voltage by accumulating carriers in the drift region 34, but by widening the arrangement interval 31b of the trenches 35 in the active region 11b, the capability to accumulate carriers decreases, and the conduction capability decreases.

In order to make the conduction capability of the active region 11b lower than the conduction capability of the active region 11a, the arrangement interval 31b of the trenches 35 in the active region 11b may be wider than the arrangement interval 31a of the trenches 35 in the active region 11a. For example, if the arrangement interval 31b is wider by 50% than the arrangement interval 31a, the conduction capability can be lowered by 3%.

The arrangement interval 31a and the arrangement interval 31b of the trench 35 can be separately formed by performing etching using etching masks having different arrangement intervals of openings in each of the active regions 11a and 11b in the etching mask for forming the trenches 35 in the manufacturing process.

### Fifth Embodiment

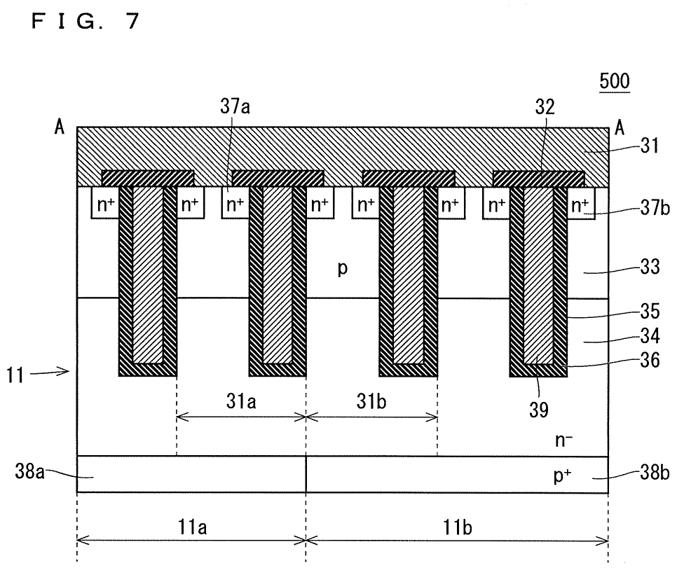

FIG. 7 is a cross-sectional view showing a configuration of a power IGBT500 according to a fifth embodiment of the present disclosure, and is a partial cross-sectional view of a semiconductor substrate 11 in the vicinity of a boundary region between an active region 11a and an active region 11b. In FIG. 7, the same components as those of the power IGBT200 described with reference to FIG. 4 are denoted by the same reference numerals, and redundant description is omitted.

In FIG. 7, collector regions are formed at different impurity concentrations in the active region 11a and the active region 11b, and the collector regions are a collector region 38a in the active region 11a and a collector region 38b in the active region 11b.

In the power IGBT500, the p⁺-type impurity concentration of the collector region 38b of the active region 11b is set to be lower than the impurity concentration of the collector region 38a of the active region 11a. With this setting, the amount of carriers in the active region 11b decreases, and the conduction capability of the active region 11b is lower than the conduction capability of the active region 11a.

In order to make the conduction capability of the active region 11b lower than the conduction capability of the active region 11a, the impurity concentration of the collector region 38b may be made lower than the impurity concentration of the collector region 38a. For example, if the impurity concentration of the collector region 38b is made lower than the impurity concentration of the collector region 38a by 50%, the conduction capability can be made lower by 26%.

The collector regions 38a and 38b can be separately formed by performing an impurity implantation process twice using an impurity implantation mask for forming the collector region 38a and an impurity implantation mask for forming the collector region 38b in the manufacturing process.

The conduction capability ratio of the active region 11b to the active region 11a shown in FIG. 3 can be adjusted to 0.9, 0.8, 0.7, and 0.6 by combining a plurality of parameters. For example, if the region width of the source region 37b is shorter than that of the source region 37a by about 50%, the conduction capability ratio can be adjusted to about 0.9. In addition, if the region width of the source region 37b is made shorter than that of the source region 37a by about 50% and the impurity concentration of the source region 37b is made lower than that of the source region 37a by about 50%, the conduction capability ratio can be adjusted to about 0.8. In addition, if the arrangement interval 31b of the trenches 35 in the active region 11b is set to be wider than the arrangement interval 31a of the trenches 35 in the active region 11a by about 50%, and the impurity concentration of the collector region 38b is set to be lower than that of the collector region 38a by about 50%, the conduction capability ratio can be adjusted to about 0.7. Further, if the region width of the source region 37b is made shorter than that of the source region 37a by about 50%, the impurity concentration of the source region 37b is made lower than that of the source region 37a by about 50%, and the impurity concentration of the collector region 38b is made lower than that of the collector region 38a by about 50%, the conduction capability ratio can be adjusted to about 0.6.

Although the present disclosure has been described in detail, the above description is exemplary in all aspects and the present disclosure is not limited thereto. It is understood that numerous modifications not shown can be assumed without departing from the scope of the present disclosure.

Note that, in the present disclosure, each embodiment can be freely combined, and each embodiment can be appropriately modified or omitted within the scope of the disclosure.

1. A power semiconductor device in which a main current flows in a thickness direction of a semiconductor substrate, the semiconductor substrate including:
a first active region provided in a central portion of the semiconductor substrate and through which the main current flows; and
a second active region provided outside the first active region, the power semiconductor device comprising:
a first main electrode provided on the first and second active regions; and
a second main electrode provided on a main surface of the semiconductor substrate opposite to the first main electrode,
wherein
the second active region has first two sides facing each other in a first direction and second two sides facing each other in a second direction orthogonal to the first direction,
a distance of the first active region from a center of the semiconductor substrate is set to less than ¼ of a shorter length of a first length between the first two sides of the second active region or a second length between the second two sides of the second active region in a case where the first length and the second length are different, and is set to less than ¼ of either length in a case where the first length and the second length have no difference, and
a first conduction capability of the first active region is set lower than a second conduction capability of the second active region.

2. The power semiconductor device according to claim 1, comprising:
a conductor plate directly bonded to the first main electrode via a first bonding layer; and
a heat dissipation plate directly bonded to the second main electrode via a second bonding layer.

3. The power semiconductor device according to claim 1, wherein
the semiconductor substrate includes:
a first semiconductor region of a second conductivity type provided on the second main electrode;
a second semiconductor region of a first conductivity type provided on the first semiconductor region;
a third semiconductor region of a second conductivity type provided on the second semiconductor region;
a plurality of fourth semiconductor regions of a first conductivity type selectively provided on an upper layer portion of the third semiconductor region;
a plurality of trenches penetrating the third semiconductor region and reaching the second semiconductor region;
a gate insulating film provided on an inner wall of each of the plurality of trenches; and
a gate electrode filled inside each of the gate insulating films,
one side surface of each of the plurality of fourth semiconductor regions is provided so as to be in contact with a side surface of each of the plurality of trenches, and
an impurity concentration of the plurality of fourth semiconductor regions in the first active region is set to be lower than an impurity concentration of the plurality of fourth semiconductor regions in the second active region.

4. The power semiconductor device according to claim 1, wherein
the semiconductor substrate includes:
a first semiconductor region of a second conductivity type provided on the second main electrode;
a second semiconductor region of a first conductivity type provided on the first semiconductor region;
a third semiconductor region of a second conductivity type provided on the second semiconductor region;
a plurality of fourth semiconductor regions of a first conductivity type selectively provided on an upper layer portion of the third semiconductor region;
a plurality of trenches penetrating the third semiconductor region and reaching the second semiconductor region;
a gate insulating film provided on an inner wall of each of the plurality of trenches; and
a gate electrode filled inside each of the gate insulating films,
one side surface of each of the plurality of fourth semiconductor regions is provided so as to be in contact with a side surface of each of the plurality of trenches, and
a region width of the plurality of fourth semiconductor regions of the first active region along an extending direction of the gate electrode is formed to be shorter than the region width of the plurality of fourth semiconductor regions of the second active region.

5. The power semiconductor device according to claim 1, wherein
the semiconductor substrate includes:
a first semiconductor region of a second conductivity type provided on the second main electrode;
a second semiconductor region of a first conductivity type provided on the first semiconductor region;
a third semiconductor region of a second conductivity type provided on the second semiconductor region;
a plurality of fourth semiconductor regions of a first conductivity type selectively provided on an upper layer portion of the third semiconductor region;
a plurality of trenches penetrating the third semiconductor region and reaching the second semiconductor region;
a gate insulating film provided on an inner wall of each of the plurality of trenches; and
a gate electrode filled inside each of the gate insulating films,
one side surface of each of the plurality of fourth semiconductor regions is provided so as to be in contact with a side surface of each of the plurality of trenches, and
an arrangement interval of the plurality of trenches in the first active region is formed to be wider than the arrangement interval of the plurality of trenches in the second active region.

6. The power semiconductor device according to claim 1, wherein
the semiconductor substrate includes:
a first semiconductor region of a second conductivity type provided on the second main electrode;
a second semiconductor region of a first conductivity type provided on the first semiconductor region;
a third semiconductor region of a second conductivity type provided on the second semiconductor region;
a plurality of fourth semiconductor regions of a first conductivity type selectively provided on an upper layer portion of the third semiconductor region;
a plurality of trenches penetrating the third semiconductor region and reaching the second semiconductor region;
a gate insulating film provided on an inner wall of each of the plurality of trenches; and
a gate electrode filled inside each of the gate insulating films,
one side surface of each of the plurality of fourth semiconductor regions is provided so as to be in contact with a side surface of each of the plurality of trenches, and
an impurity concentration of the first semiconductor region in the first active region is set to be lower than an impurity concentration of the first semiconductor region in the second active region.

7. The power semiconductor device according to claim 2, wherein
the second main electrode is provided over the entire main surface of the semiconductor substrate, and
the second bonding layer is provided over an entire main surface of the second main electrode.
